(19) United States
(12) Patent Application Publication
(10) Pub. No.: US 2013/0181305 A1
(43) Pub. Date: Jul. 18, 2013

(54) MAGNETORESISTIVE ELEMENT AND MAGNETIC RANDOM ACCESS MEMORY

(71) Applicant: KABUSHIKI KAISHA TOSHIBA, Tokyo (JP)

(72) Inventors: Masahiko Nakayama, Yokohama-shi (JP); Hiroaki Yoda, Kawasaki-shi (JP); Tatsuya Kishi, Yokohama-shi (JP); Jyunichi Ozeki, Yokosuka-shi (JP); Tadashi Kai, Tokyo (JP); Hisanori Aikawa, Yokohama-shi (JP); Sumio Ikegawa, Yokohama-shi (JP)

(73) Assignee: KABUSHIKI KAISHA TOSHIBA, Tokyo (JP)

(21) Appl. No.: 13/781,529

(22) Filed: Feb. 28, 2013

(30) Foreign Application Priority Data
Sep. 17, 2010 (JP) 2010-210181

(51) Int. Cl. H01L 43/02

(52) U.S. Cl. CPC H01L 43/02
USPC 257/421

(57) ABSTRACT

A magnetoresistive element according to an embodiment includes: a first ferromagnetic layer having changeable magnetization substantially perpendicular to a film plane; a second ferromagnetic layer having fixed magnetization substantially perpendicular to the film plane; a first nonmagnetic layer provided between the first ferromagnetic layer and the second ferromagnetic layer; a third ferromagnetic layer provided on the opposite side of the second ferromagnetic layer from the first nonmagnetic layer, the third ferromagnetic layer having magnetization substantially parallel to the film plane, the third ferromagnetic layer generating a rotating magnetic field when spin-polarized electrons are injected thereinto; and a second nonmagnetic layer provided between the second ferromagnetic layer and the third ferromagnetic layer.

### CROSS-REFERENCE TO RELATED APPLICATION

This application is a Continuation Application of and claims the benefit of priority from prior Japanese Patent Application No. 2010-210181 filed on Sep. 17, 2010 in Japan, and International Application No. PCT/JP2011/071254 filed on Sep. 16, 2011, the entire contents of which are incorporated herein by reference.

### FIELD

Embodiments described herein relate generally to magnetoresistive elements and magnetic random access memories.

### BACKGROUND

Various types of solid-state magnetic memories have been conventionally suggested. In recent years, magnetic random access memories (MRAMs) using magnetoresistive elements each having a giant magnetoresistive (GMR) effect have been suggested, and particularly, attention is now being drawn to magnetic random access memories using ferromagnetic tunnel junctions each having a tunneling magnetoresistive (TMR) effect.

A MTJ (Magnetic Tunnel Junction) element having a ferromagnetic tunnel junction is formed mainly with the three layers: a first ferromagnetic layer, an insulating layer, and a second ferromagnetic layer. At the time of reading, a current flows, tunneling through the insulating layer. In this case, the resistance value of the ferromagnetic tunnel junction varies depending on the cosine of the relative angle between the magnetization of the first ferromagnetic layer and the magnetization of the second ferromagnetic layer. For example, the resistance value of the ferromagnetic tunnel junction becomes smallest when the magnetization directions of the first and second ferromagnetic layers are parallel (the same directions), and becomes largest when the magnetization directions are antiparallel (the opposite directions). This is the above described TMR effect. There are cases where the variation in the resistance value caused by the TMR effect exceeds 300% at room temperature.

In a magnetic memory device including MTJ elements with ferromagnetic tunnel junctions as memory cells, at least one ferromagnetic layer is regarded as a reference layer, and the magnetization direction of the ferromagnetic layer is pinned. The other ferromagnetic layer is regarded as a recording layer. In such a cell, information is stored by associating binary information “0” or “1” with a parallel state or an antiparallel state of magnetization directions of the reference layer and the recording layer. Alternatively, “1” or “0” may be associated with a parallel state or an antiparallel state of the magnetization directions of the reference layer and the recording layer. Conventionally, recording information is written by reversing the magnetization of the recording layer with a magnetic field generated by flowing a current to a write line provided separately for this cell. By the write method using a magnetic field generated by flowing a current, however, the current required for writing increases as the memory cell is made smaller in size. As a result, increasing the capacity becomes difficult.

In recent years, a method of reversing magnetization of a magnetic material has been suggested to replace the write method using a magnetic field generated by flowing a current. By this method, the magnetization of the recording layer is reversed by a spin torque injected from the reference layer when a current is flowed directly to the MTJ element (hereinafter referred to as the spin-transfer torque writing method). The spin-transfer torque writing method is characterized in that the current required for writing decreases as the memory cell is made smaller in size, and increasing the capacity is easy. Information is read from a memory cell by flowing a current to the ferromagnetic tunnel junction and detecting a resistance change by virtue of the TMR effect.

A magnetic memory is formed by providing a large number of such memory cells. In an actual structure, a switching transistor is provided for each memory cell as in a DRAM, for example, so that any cell can be selected. Peripheral circuits are also incorporated into the structure. The spin-transfer torque writing method is suitable for reducing the current required for information writing as described above. However, to reverse magnetization, a current that flows bi-directionally is required, and the number of peripheral circuits required for driving becomes larger.

To solve this problem, there is a suggested method of causing magnetization reversals in directions corresponding to the information “0” and “1” by flowing a current in one direction, changing the amount of current and the pulse width, and taking advantage of the difference in the amount of spin-transfer torque writing current under the respective conditions. When such a technique is used, changing the pulse width is a necessary parameter in determining a magnetization reversing direction.

Therefore, to perform stable writing without a writing error, the pulse width needs to be made sufficiently large when information is written in a direction corresponding to the information “0” or “1”. This presents a problem in terms of high-speed memory operations. Further, to match an integral multiple of the precession of a magnetic material with the pulse width as in the above described suggestion, the pulse width needs to be precisely controlled for each element in the memory cell. In actual memory cells, however, there are delays due to variations in capacity between lines and variations in pulse waveform. Therefore, precise control of pulse widths of elements is required.

### BRIEF DESCRIPTION OF THE DRAWINGS

FIGS. 1(a) and 1(b) are diagrams showing resonance phenomena caused by a high-frequency magnetic field of a magnetic material;

FIG. 2 is a graph showing the frequency dependence of the perpendicular magnetization component;

FIG. 3 is a diagram showing the results of a simulated magnetized state at the time of resonant magnetic field writing with a microwave magnetic field;

FIG. 4 is a diagram showing the results of a simulated magnetized state where a clockwise microwave magnetic field was applied;

FIG. 5 is a cross-sectional view of a magnetoresistive element according to a first embodiment;

FIG. 6 is a schematic view of the magnetoresistive element of the first embodiment at the time of application of a microwave magnetic field;

FIG. 7 is a diagram showing the current dependence of the rotational frequency of the magnetic rotation layer;

FIGS. 8(a) and 8(b) are diagrams for explaining a magnetization reversal from a parallel state to an antiparallel state in the magnetoresistive element of the first embodiment; FIGS. 9(a) and 9(b) are diagrams for explaining a magnetization reversal from an antiparallel state to a parallel state in the magnetoresistive element of the first embodiment;

FIGS. 10(a) and 10(b) are diagrams showing the results of magnetization reversal simulations in the magnetoresistive element of the first embodiment;

FIGS. 11(a) and 11(b) are diagrams showing the results of magnetization reversal simulations in the magnetoresistive element of the first embodiment;

FIG. 12 is a cross-sectional view of a magnetoresistive element according to a second embodiment;

FIG. 13 is a cross-sectional view of a magnetoresistive element according to a modification of the second embodiment;

FIG. 14 is a cross-sectional view of a magnetoresistive element according to a third embodiment;

FIG. 15 is a cross-sectional view of a magnetoresistive element according to a fourth embodiment;

FIG. 16 is a cross-sectional view of a magnetoresistive element according to a modification of the fourth embodiment;

FIG. 17 is a circuit diagram of an MRAM according to a fifth embodiment; and

FIG. 18 is a circuit diagram of an MRAM according to a sixth embodiment

### DETAILED DESCRIPTION

A magnetoresistive element according to an embodiment includes: a first ferromagnetic layer having changeable magnetization substantially perpendicular to a film plane; a second ferromagnetic layer having fixed magnetization substantially perpendicular to the film plane; a first nonmagnetic layer provided between the first ferromagnetic layer and the second ferromagnetic layer; a third ferromagnetic layer provided on the opposite side of the second ferromagnetic layer from the first nonmagnetic layer, the third ferromagnetic layer having magnetization substantially parallel to the film plane, the third ferromagnetic layer generating a rotating magnetic field when spin-polarized electrons are injected thereinto; and a second nonmagnetic layer provided between the second ferromagnetic layer and the third ferromagnetic layer, wherein the magnetization of the first ferromagnetic layer is reversed by the rotating magnetic field generated from the third ferromagnetic layer when a first current is flowed in one of a direction from the third ferromagnetic layer toward the first ferromagnetic layer via the second ferromagnetic layer and a direction from the first ferromagnetic layer toward the third ferromagnetic layer via the second ferromagnetic layer, and, when a second current having a different current density from the first current is flowed in the one direction, the magnetization of the first ferromagnetic layer is reversed by electrons spin-polarized by the second ferromagnetic layer to a different direction from the magnetization caused when the first current is flowed.

The principles of resonant magnetic field writing used in each embodiment are described now before the respective embodiments are described.

In a magnetoresistive element according to an embodiment, not only a spin torque write method but also a resonant magnetic field write method to be performed by applying a microwave magnetic field is used, so as to perform stable magnetization reversal writing in directions corresponding to information “0” and “1” by using a unidirectional current without a writing error.

Generally, a magnetic material has a natural resonant frequency that resonates with a microwave magnetic field in accordance with anisotropy energy and saturation magnetization. When a microwave magnetic field corresponding to the resonant frequency is applied, in a direction parallel to the film plane, to a magnetic material having a magnetization direction perpendicular to the film plane (hereinafter also referred to as the perpendicular magnetization), a resonance phenomenon occurs, and the perpendicular magnetization quickly tilts toward the direction parallel to the film plane, to start to precess.

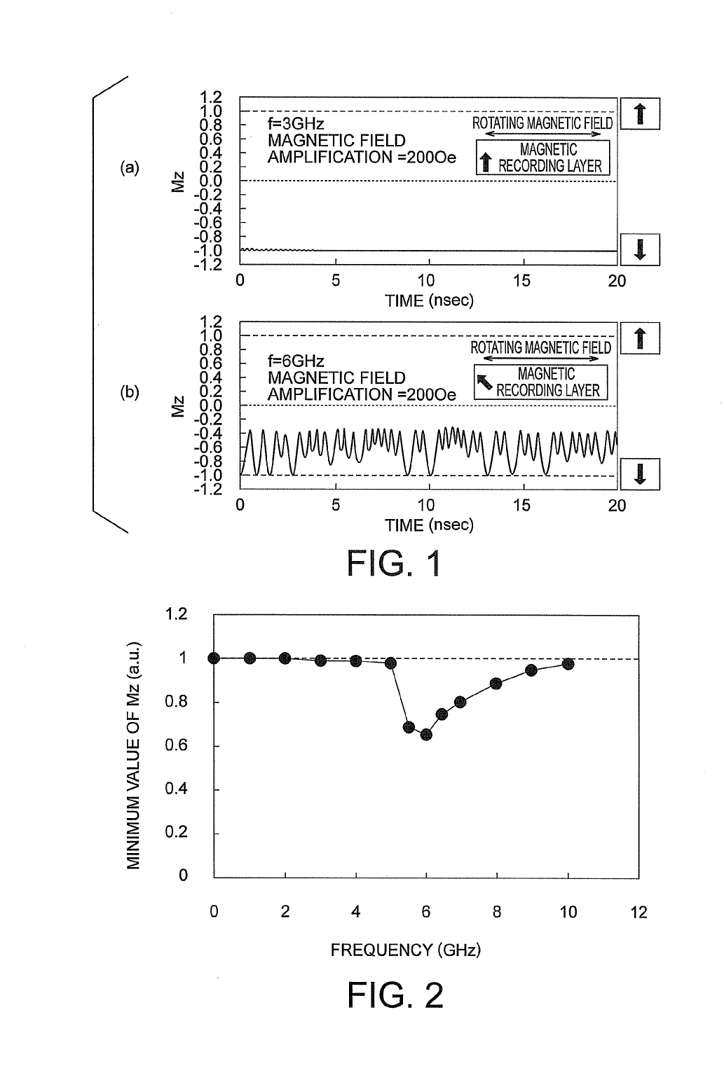

Here, the film plane means the upper surface of a magnetic material. A disk-like magnetic recording layer of 30 nm in diameter is prepared, and this magnetic recording layer has perpendicular magnetization, as well as the following magnetic parameters: a saturation magnetization Ms of 800 emu/cc and a magnetic anisotropy energy Ku of 1.0×10⁷ erg/cc. In one case, a microwave magnetic field that has a plane of rotation parallel to the film plane of the magnetic recording layer, and rotates counterclockwise when viewed from above is applied to the magnetic recording layer. FIGS. 1(a) and 1(b) show the results of simulations performed to calculate the magnetization components in the direction perpendicular to the film plane of the magnetic recording layer in this case. The simulated calculation results shown in FIGS. 1(a) and 1(b) are to be obtained where the rotational frequencies (hereinafter also referred to simply as the frequencies) of microwave magnetic fields are 3 GHz and 6GHz, and the amplifications are the same at 200 Oe. In each of FIGS. 1(a) and 1(b), the abscissa axis indicates magnetization, and the ordinate axis indicates the magnetization component Mz in the direction perpendicular to the film plane of the magnetic recording layer. In FIGS. 1(a) and 1(b), when the value of Mz is 1.0, the magnetization direction of the magnetic recording layer is an upward direction. When the value of Mz is −1.0, the magnetization direction of the magnetic recording layer is a downward direction.

In the simulated calculation, when the frequency of the applied microwave magnetic field is 3 GHz, the magnetization direction of the magnetic recording layer is a downward direction, which is the same as the magnetization direction in the initial state prior to the application of the microwave magnetic field, and this magnetization direction hardly changes, as shown in FIG. 1(a). When the frequency of the applied microwave magnetic field is 6 GHz, on the other hand, the magnetization of the magnetic recording layer is clearly in a resonant state, and the magnetization tilts toward the direction parallel to the film plane from the direction perpendicular to the film plane.

FIG. 2 shows the frequency dependence of a microwave magnetic field with respect to the minimum value of the magnetization component Mz in the direction perpendicular to the film plane, which is obtained by changing the frequency of the microwave magnetic field. Here, the minimum value of the magnetization component Mz in the direction perpendicular to the film plane means the absolute value of the magnetization component Mz perpendicular to the film plane when a microwave magnetic field is applied and the magnetization is put into a resonant state and has the largest tilt. As can be seen from FIGS. 1(a) and 1(b), a resonance phenomenon occurs in the magnetic recording layer at approximately 6 GHz, and the magnetization of the magnetic recording layer tilts. What matters here is that, when the magnetization component Mz perpendicular to the film plane is made to move across zero, or change from positive to negative or vice versa, by a microwave magnetic field, a magnetization reversal can be caused.

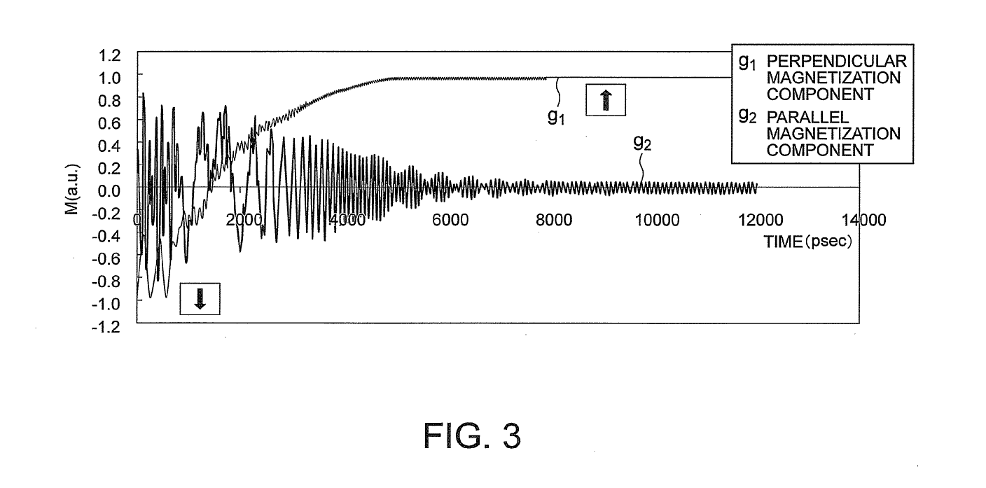

A magnetic recording layer that has perpendicular magnetization, a saturation magnetization of 500 emu/cc, and an anisotropy energy Ku of 2.0×10⁶ erg/cc is prepared. FIG. 3 shows the results of a simulation performed to measure the time dependence of magnetization when a microwave magnetic field having a plane of rotation parallel to the film plane of the magnetic recording layer is applied. In this simulation, the magnetization direction of the magnetic recording layer is substantially perpendicular to the film plane and is a downward direction prior to the application of the microwave magnetic field. The microwave magnetic field is a rotating magnetic field that rotates counterclockwise when viewed from above. FIG. 3 shows the vector of the magnetization decomposed into the component perpendicular to the film plane (the perpendicular magnetization component) and the component parallel to the film plane (the parallel magnetization component). The perpendicular magnetization component is shown by a graph g₁, and the parallel magnetization component is shown by a graph g₂. When a microwave magnetic field is applied, the parallel magnetization component clearly starts to precess, and the perpendicular magnetization component tilts with time. At around 1500 psec, the sign of the perpendicular magnetization component changes from negative to positive, or the magnetization direction changes from downward to upward, which means that a magnetization reversal has occurred. This proves that a magnetization reversal occurs when a microwave magnetic field having a frequency that resonates with the magnetization of the magnetic recording layer (a resonant frequency) is applied to the magnetic recording layer having perpendicular magnetization as described above.

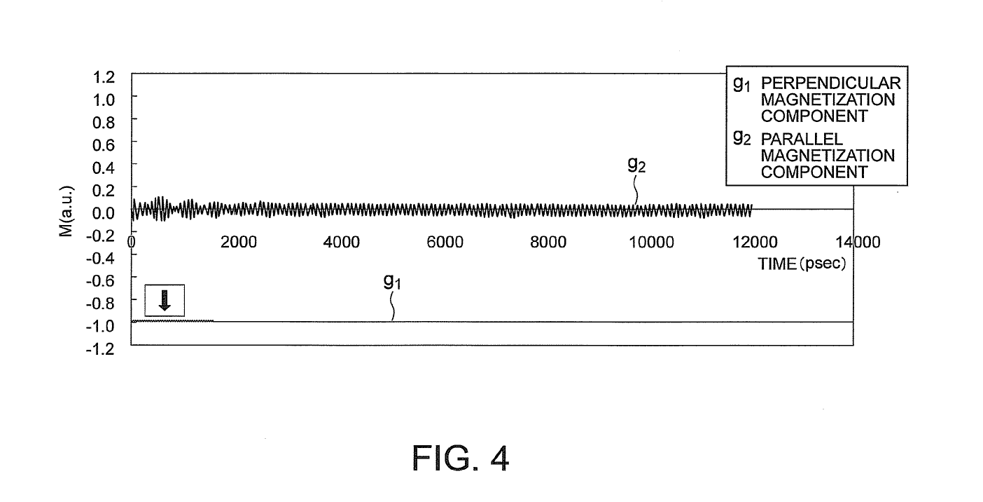

Further, what also matters in resonant magnetic field writing is that magnetization reversing directions of the magnetic recording layer and directions of rotation of the microwave magnetic field have one-to-one correspondence. FIG. 4 shows the results of a simulation performed to calculate the time dependence of the magnetization when the direction of rotation of the microwave magnetic field is clockwise under the same conditions as those in the simulation shown in FIG. 3. As can be seen from FIG. 4, it has become apparent that, when the direction of rotation is simply reversed, the perpendicular magnetization component (shown by a graph g₁) hardly changes, but the parallel magnetization component (shown by a graph g₂) fluctuates. To sum up, the magnetization of the magnetic recording layer can be reversed to a desired direction by applying a microwave magnetic field having a predetermined rotational frequency and a predetermined direction of rotation to the magnetic recording layer. It should be noted that a rotating magnetic field corresponding to the resonant frequency should be applied to the magnetic recording layer, but the rotating magnetic field is not limited to a microwave magnetic field The following is a description of embodiments of the present invention, with reference to the accompanying drawings.

### First Embodiment

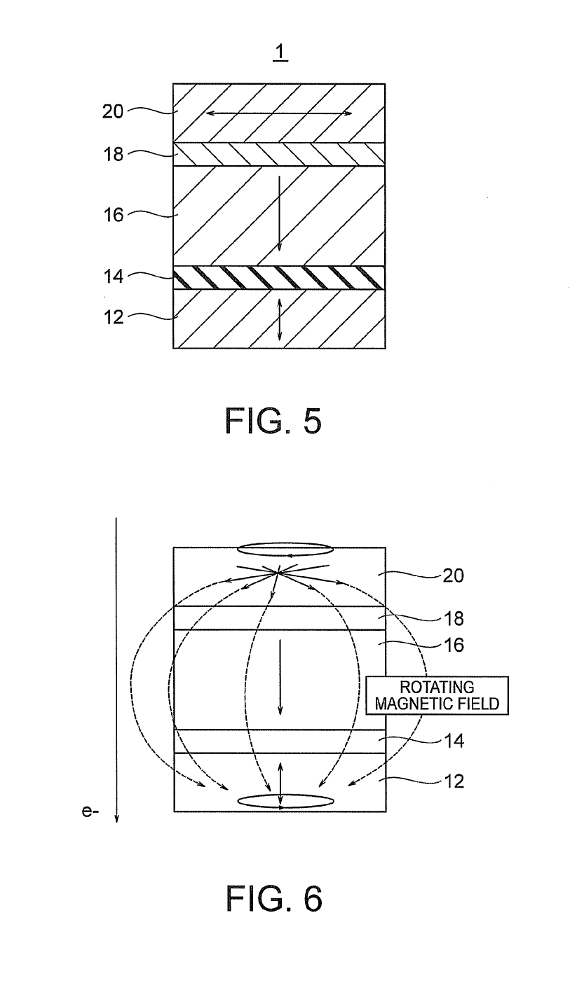

FIG. 5 shows a magnetoresistive element according to a first embodiment. The magnetoresistive element 1 of this embodiment has a stack structure formed by stacking a magnetic recording layer 12 having a variable magnetization direction, a tunnel barrier layer 14, a magnetic reference layer 16 having a substantially fixed magnetization direction, a spacer layer 18, and a magnetic rotation layer 20 in this order, or a stack structure formed by stacking those layers in reverse order.

The magnetic recording layer 12 includes a ferromagnetic layer that has a magnetization direction substantially perpendicular to the film plane and can change the magnetization direction before and after flowing a current when a current is flowed to the magnetoresistive element 1. The magnetic reference layer 16 includes a ferromagnetic layer that has a magnetization direction substantially perpendicular to the film plane and keeps the magnetization direction before and after flowing a current even when a current is flowed to the magnetoresistive element 1. In this embodiment, the magnetization direction of the magnetic reference layer 16 is a downward direction as shown in FIG. 5. The magnetic rotation layer 20 includes a ferromagnetic layer that has a magnetization direction substantially parallel to the film plane and has its magnetization rotating in a substantially parallel plane when a current is applied to the magnetoresistive element 1.

The tunnel barrier layer 14 is made of an oxide or a nitride containing an element selected from the group consisting of Mg, Al, Ti, and Hf, which causes electrons to tunnel therethrough, and causes a desired change in magnetoresistance. The spacer layer 18 is a nonmagnetic layer that passes spin-polarized electrons, and the material of the spacer layer 18 may be a metal made only of one element selected from the group consisting of Cu, Au, Ru, and Ag, or an alloy containing at least one of those elements, for example. Alternatively, the spacer layer 18 may be made of an oxide or a nitride containing one element selected from the group consisting of Mg, Al, Ti, and Hf.

In the magnetoresistive element 1 of this embodiment, information is recorded, depending on the magnetization direction of the magnetic recording layer 12. Therefore, the magnetic recording layer 12 needs to be made of a magnetic material having a sufficiently large perpendicular magnetic anisotropy, and secure stability against thermal disturbance. In view of this, the optimum magnetic material as the magnetic recording layer 12 is preferably an ordered alloy or a disordered alloy containing at least one element selected from the group consisting of Fe, Co, and Ni, and at least one element selected from the group consisting of Cr, Pt, Pd, and Ta. For example, the magnetic recording layer 12 is preferably formed with a magnetic material having an L1₀ crystal structure containing at least one element selected from the group consisting of Fe, Co, and Ni, and at least one element selected from the group consisting of Pt and Pd. Alternatively, the magnetic recording layer 12 is preferably formed with a magnetic material having a hexagonal crystal structure containing at least one element selected from the group consisting of Fe, Co, and Ni, and at least one element selected from the group consisting of Cr, Pt, Pd, and Ta. Also, the magnetic recording layer 12 may be formed with an ordered alloy or a disordered alloy containing one or more elements of rare-earth metals Sm, Gd, Tb, and Dy.

In this embodiment, the magnetic rotation layer 20 is used as the generation source of microwave magnetic fields. When spin-polarized electrons are injected into this magnetic rotation layer 20, the magnetization of the magnetic rotation layer 20 rotates in the direction in which a left-handed screw rotates when the left-handed screw travels in the direction of spins of the spin-polarized electrons injected into the magnetic rotation layer 20. This embodiment concerns a case where a write current is flowed from the magnetic recording layer 12 to the magnetic rotation layer 20 via the tunnel barrier layer 14, the magnetic reference layer 16, and the spacer layer 18, or a case where electrons flow from the magnetic rotation layer 20 to the magnetic recording layer 12 via the spacer layer 18, the magnetic reference layer 16, and the tunnel barrier layer 14. Since the magnetization direction of the magnetic reference layer 16 is a downward direction in this case, the electrons that have passed through the magnetic rotation layer 20 are spin-polarized by the magnetic reference layer 16, and are divided into spin-polarized electrons having spins in the same direction as the magnetization of the magnetic reference layer 16 and spin-polarized electrons having spins in the opposite direction from the magnetization of the magnetic reference layer 16. The spin-polarized electrons having spins in the same direction as the magnetization of the magnetic reference layer 16 pass through the magnetic reference layer 16. However, the spin-polarized electrons having spins in the opposite direction from the magnetization of the magnetic reference layer 16 are reflected by the magnetic reference layer 16, and are injected into the magnetic rotation layer 20 via the spacer layer 18, to start rotation of the magnetization of the magnetic rotation layer 20. Since the spin-polarized electrons injected into the magnetic rotation layer 20 are in an upward direction, the rotation of the magnetization of the magnetic rotation layer 20 is in a clockwise direction when the magnetic rotation layer 20 is viewed from above.

In this embodiment, when a current is flowed in the opposite direction from that in the above case, or when electrons are made to flow into the magnetic rotation layer 20 via the magnetic recording layer 12, the tunnel barrier layer 14, the magnetic reference layer 16, and the spacer layer 18, the spin-polarized electrons injected into the magnetic rotation layer 20 have spins in the same downward direction as the magnetization of the magnetic reference layer 16. Therefore, the magnetization of the magnetic rotation layer 20 rotates in a counterclockwise direction when the magnetic rotation layer 20 is viewed from above.

FIG. 6 illustrates a situation where a microwave magnetic field generated by rotation of the magnetization of the magnetic rotation layer 20 is applied to the magnetic recording layer 12. The rotational frequency fᵢ obtained when spin-polarized electrons are injected into the magnetic rotation layer 20 is expressed by the following equations, as the LLG (Landau-Lifshitz-Gilbert) equation is solved (see M. Mansuripur, J. Appl. Phys., 63:5809, 1988, for example).

$$\begin{matrix}{f}_{i} = \frac{γ}{2 π α} ( \frac{ℏ}{2 e} ) \frac{g ( {θ}_{1} )}{{M}_{s} t} J & ( 1 ) \\ g ( θ ) = \frac{1}{2} \frac{P}{1 + {P}^{2} cos θ} & ( 2 ) \\ {θ}_{1} = {cos}^{- 1} [ \frac{H z - {α}_{j} ( π / 2 ) / α}{4 π {M}_{s} + Hk / 2} ] & ( 3 ) \\ {α}_{J} ( θ ) = \frac{ℏ}{2 e} \frac{g ( θ )}{{M}_{s} t} J & ( 4 )\end{matrix}$$

Here, γ represents the gyromagnetic constant, a represents the damping factor, the h-bar represents the Dirac constant as the value obtained by dividing the Planck's constant by 27π, e represents the elementary charge, Ms represents the saturation magnetization, t represents the film thickness of the magnetic rotation layer 20, J represents the density of current flowing in the magnetic rotation layer, P represents the polarizability, Hz represents the magnetic field applied to the magnetic rotation layer 20 (a magnetic field strayed from the magnetic reference layer 16, for example), and Hk represents the magnetic anisotropy field of the magnetic rotation layer 20.

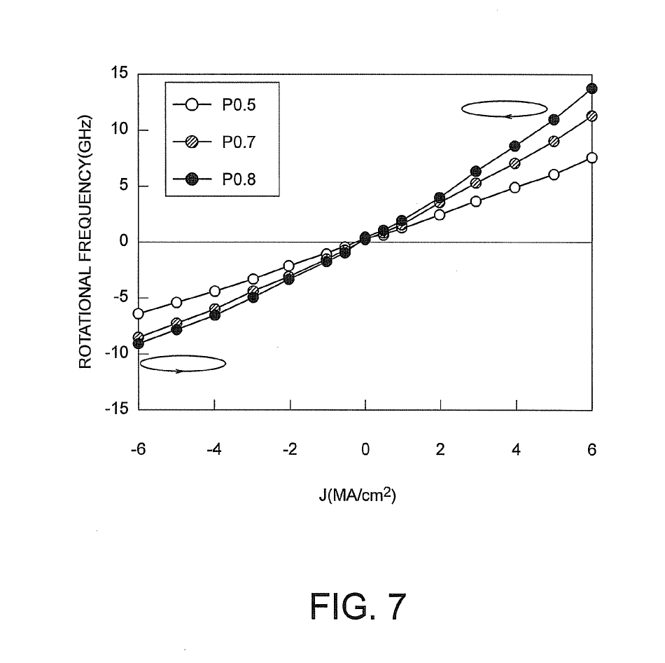

FIG. 7 shows the current density dependence of the rotational frequency (the precessional frequency) which was calculated by using the above equations when a current was flowed to the magnetic rotation layer 20. Here, when the magnetic rotation layer 20 is viewed from above, the rotational frequency is positive in a case where the rotation is in a clockwise direction, and is negative in a case where the rotation is in a counterclockwise direction. The current density 3 is positive when the current is flowed from the magnetic recording layer 12 to the magnetic rotation layer 20 via the tunnel barrier layer 14, the magnetic reference layer 16, and the spacer layer 18, and is negative when the current is flowed in the reverse direction. As can be seen from FIG. 7, the rotational frequency of the magnetic rotation layer 20 can be adjusted by adjusting the current density 3 and a magnetic parameter (the saturation magnetization Ms or the polarizability P) of the magnetic rotation layer 20. For example, the absolute value of the rotational frequency can be made larger by increasing the absolute value of the current density J, and, if the current density J is constant, the absolute value of the rotational frequency can be made larger by increasing the polarizability P. What matters here is that resonant magnetic field writing can be performed as described above if the rotational frequency of the magnetic rotation layer 20 matches the resonant frequency of the magnetic recording layer 12 at a desired current density 3, and resonant magnetic field writing does not occur if the current density 3 is changed so that the rotational frequency differs from the resonant frequency of the magnetic recording layer 12. By taking advantage of such characteristics, the magnetization direction of the magnetic recording layer 12 can be reversed in accordance with information “0” or “1”, with the use of the unidirectional current, which is a feature of an embodiment of the present invention.

A preferred value of the resonant frequency of the magnetic recording layer 12 can be determined by the thermal disturbance index and the dependence of the resonant frequency. The resonant frequency of the magnetic recording layer 12 is expressed by the following Kittel's equation:

$$f = 2 γ ( \frac{2 {K}_{u}}{{M}_{s}} - 4 π {M}_{s} ) = 4 γ \frac{2 {K}_{ueff}}{{M}_{s}} \qquad ( 5 )$$

Here, f represents the resonant frequency, Kᵤ represents the magnetic anisotropy energy of the magnetic recording layer 12, Mₛ represents the saturation magnetization of the magnetic recording layer 12, γ represents the gyro constant, and K_{ueff} represents the effective magnetic anisotropy energy with a diamagnetic field taken into consideration.

Meanwhile, the thermal disturbance index is expressed as the product of the effective magnetic anisotropy energy K_{ueff} and the volume of the magnetoresistive element. In a magnetic memory, a thermal disturbance index needs to be set so as not to cause an abnormal reversal due to heat, with variations of magnetoresistive elements being taken into consideration. The thermal disturbance index is preferably 30 to 120. When the thermal disturbance index is 30 to 120, the range of preferred resonant frequencies for the magnetic recording layer 12 to cause resonant magnetic field writing is 2 GHz to 40 GHz.

To increase the rotation efficiency, the magnetic rotation layer 20 is preferably an in-plane magnetization film having a high polarizability. The magnetic rotation layer 20 is preferably formed with a magnetic material containing at least one element selected from the group consisting of Fe, Co, and Ni, and at least one element selected from the group consisting of B, Si, and C, or is preferably formed with an alloy containing at least one element selected from the group consisting of Fe, Co, and Ni (such as CoFe, Fe, or CoFeNi).

To perform stable spin injection into the magnetic recording layer 12 and the magnetic rotation layer 20, and to increase the rotation efficiency, the magnetic reference layer 16 preferably has a large perpendicular magnetic anisotropy, and is preferably formed with a magnetic material that has a perpendicular magnetic anisotropy and contains at least one element selected from the group consisting of Fe, Co, and Ni, and at least one element selected from the group consisting of Cr, Ta, Pt, and Pd. Alternatively, the magnetic reference layer 16 may be formed with a magnetic material that has a perpendicular magnetic anisotropy and contains at least one of rare-earth elements such as Tb, Dy, Gd, and Ho, and at least one element selected from the group consisting of Fe, Co, and Ni. In view of the fact that the magnetic reference layer 16 needs to have a higher polarizability than the magnetic recording layer 12 and the magnetic rotation layer 20, the magnetic reference layer 16 may be a stack-type magnetic reference layer formed with a stack structure in which the above described magnetic material of the magnetic reference layer, and a magnetic material containing at least one element selected from the group consisting of Fe, Co, and Ni, and at least one element selected from the group consisting of B, Si, and C, are stacked, or the magnetic reference layer 16 may be a stack-type magnetic reference layer formed with a stack structure in which the magnetic material of the above described magnetic reference layer and an alloy containing at least one element selected from the group consisting of Fe, Co, and Ni (such as CoFe, Fe, or CoFeNi) are stacked.

The magnetoresistive element 1 of this embodiment is characterized by having two different writing mechanisms that cause magnetization reversals in the magnetic recording layer 12. One is spin-transfer torque writing performed by injecting spin-polarized electrons from the magnetic reference layer 16 into the magnetic recording layer 12 via the tunnel barrier layer 14 when a write current is flowed from the magnetic recording layer 12 to the magnetic rotation layer 20 via the tunnel barrier layer 14, the magnetic reference layer 16, and the spacer layer 18. The other one is resonant magnetic field writing to be performed by injecting spin-polarized electrons reflected by the magnetic reference layer 16 into the magnetic rotation layer 20 via the spacer layer 18, and applying the microwave magnetic field generated from the magnetic rotation layer 20 to the magnetic recording layer 12. By the resonant magnetic field writing, magnetization is written in the same direction as the traveling direction of a left-handed screw when the left-handed screw rotates in the direction of rotation of the microwave magnetic field applied to the magnetic recording layer 12. If the element is designed so that reversal directions differ between the spin-transfer torque writing and the resonant magnetic field writing, and reversal current values differ between the respective writing mechanisms, the magnetization direction can be reversed in accordance with the information “0” and “1” by flowing unidirectional currents of different current values.

Particularly, in the resonant magnetic field writing, the current value necessary for the resonant magnetic field writing can be flexibly changed by changing the magnetization of the magnetic rotation layer 20 and a magnetic parameter such as the polarizability P as described above. The direction of rotation of the magnetization can be changed by reversing the orientation of the magnetic reference layer 16 or using a synthetic antiferromagnetic coupling film as the magnetic rotation layer 20 as will be described later in a third embodiment.

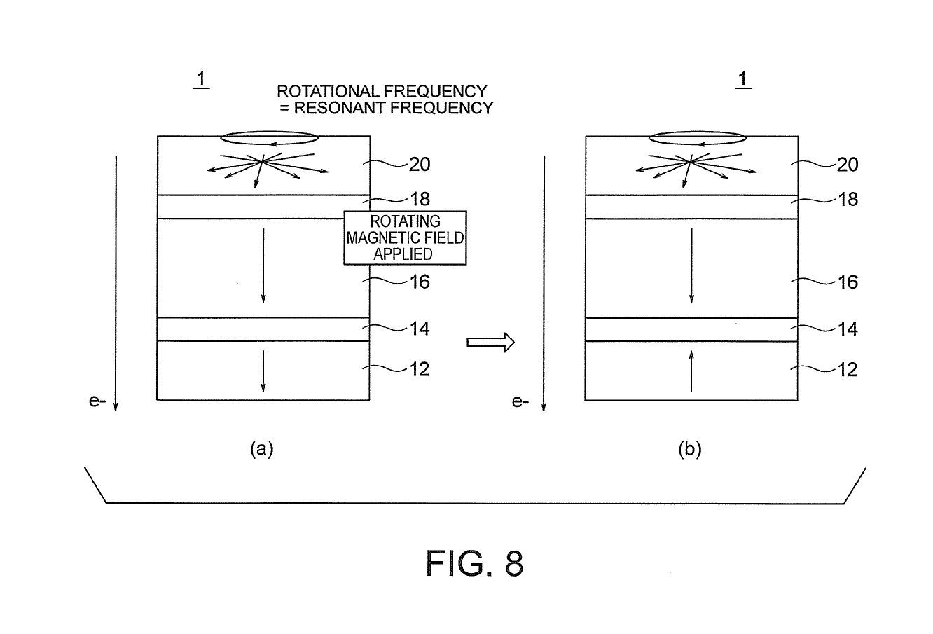

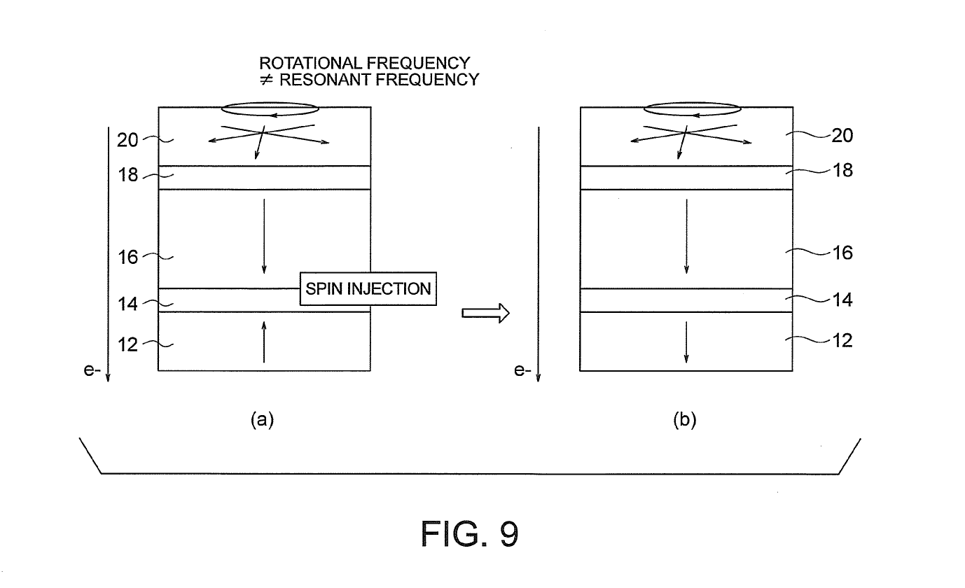

Referring now to FIGS. 8(a) and 8(b), a case where the magnetization direction of the magnetic recording layer 12 with respect to the magnetization direction of the magnetic reference layer 16 is reversed from a parallel state to an antiparallel state in the magnetoresistive element 1 of this embodiment is described. In FIG. 8(a), the magnetization directions of the magnetic recording layer 12 and the magnetic reference layer 16 are parallel and downward. In this situation, a first write current that has the same rotational frequency as the resonant frequency of the magnetic recording layer 12 or has a current density at which the magnetic rotation layer 20 generates a microwave magnetic field close to the resonant frequency is flowed from the magnetic recording layer 12 to the magnetic rotation layer 20 via the tunnel barrier layer 14, the magnetic reference layer 16, and the spacer layer 18. In this case, the first write current has such a current value that the spin-transfer torque generated when the electrons that are spin-polarized by the magnetic reference layer 16 and have spins in the same direction as the magnetization of the magnetic reference layer 16 act on the magnetic recording layer 12 becomes smaller than the reverse torque generated in the magnetic recording layer 12 by the resonant magnetic field. Therefore, even when the first write current is flowed, spin-transfer torque writing does not occur, but resonant magnetic field writing occurs. By the resonant magnetic field writing, the magnetization direction of the magnetic recording layer 12 with respect to the magnetization direction of the magnetic reference layer 16 is changed from a parallel state to an antiparallel state (FIG. 8(b)). That is, a magnetization reversal occurs.

Referring now to FIGS. 9(a) and 9(b), a case where the magnetization direction of the magnetic recording layer 12 with respect to the magnetization direction of the magnetic reference layer 16 is reversed from an antiparallel state to a parallel state in the magnetoresistive element 1 of this embodiment is described. In FIG. 9(a), the magnetization directions of the magnetic recording layer 12 and the magnetic reference layer 16 are antiparallel, and the magnetization direction of the magnetic recording layer 12 is upward. In this situation, a second write current is flowed. The second write current is selected so that the rotational frequency of the microwave magnetic field generated from the magnetic rotation layer 20 by this current differs from the resonant frequency of the magnetic recording layer 12. Accordingly, even when the second write current is flowed, resonant magnetic field writing does not occur. However, the second write current has such a current value that the spin-polarized electrons that are spin-polarized by the magnetic reference layer 16 and have spins in the same direction as the magnetization of the magnetic reference layer 16 are injected into the magnetic recording layer 12, to cause a spin injection reversal. By the spin injection reversal, the magnetization direction of the magnetic recording layer 12 with respect to the magnetization direction of the magnetic reference layer 16 changes from an antiparallel state to a parallel state (FIG. 9(b)). That is, a magnetization reversal occurs. What matters here is that the frequency of the microwave magnetic field and the resonant frequency can be changed by changing magnetic parameters of the magnetic rotation layer 20 and the magnetic recording layer 12.

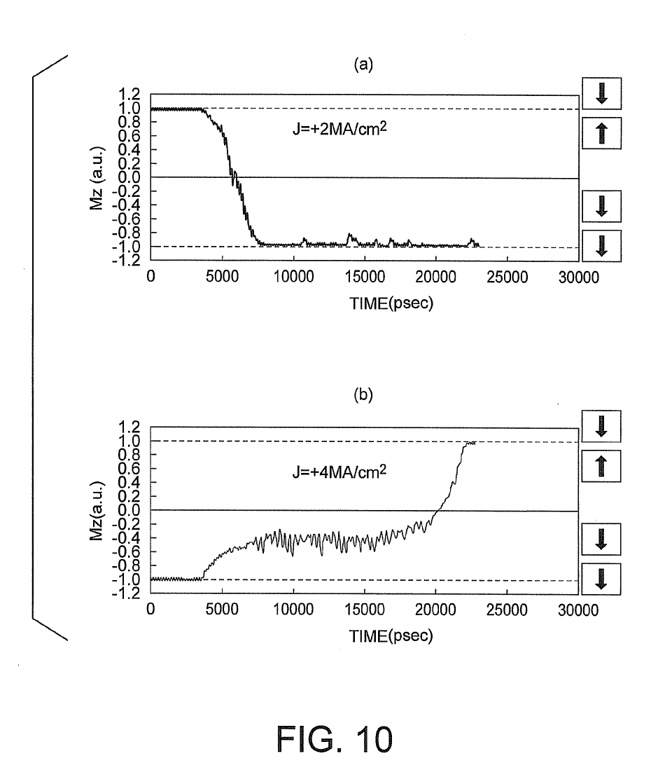

FIGS. 10(a) and 10(b) each show the result of writing using a unidirectional current calculated through an LLG simulation in the magnetoresistive element 1 of this embodiment as a model. FIG. 10(a) shows the result of a simulation in which the current density is 2 MA/cm², and FIG. 10(b) shows the result of a simulation in which the current density is 4 MA/cm². The pairs of arrows shown at the top and bottom of each of FIGS. 10(a) and 10(b) are pairs indicating the magnetization directions of the magnetic reference layer 16 and the magnetic recording layer 12. In each of the pairs, the upper arrow indicates the magnetization direction of the magnetic reference layer 16, and the lower arrow indicates the magnetization direction of the magnetic recording layer 12. As can be seen from FIGS. 10(a) and 10(b), a magnetization reversal from an antiparallel state to a parallel state is caused by spin-transfer torque writing at the current density of 2 MA/cm², and a magnetization reversal from a parallel state to an antiparallel state is caused by resonant magnetic field writing at the current density of 4 MA/cm². In FIG. 10(b), the reverse torque generated by the resonant magnetic field writing and the reverse torque generated by the spin-transfer torque writing acts in the opposite directions from each other during the writing, and the magnetization direction of the magnetic recording layer fluctuates. However, the reverse torque generated by the resonant magnetic field writing becomes gradually dominant, and the resonant magnetic field writing is performed. In the magnetoresistive element 1 of this embodiment, a magnetization direction reversal can be caused in accordance with the information “0” and “1” by changing the current density of the unidirectional current. Accordingly, it becomes unnecessary to precisely control the pulse width, and stable writing can be performed without a writing error.

Although the magnetization direction of the magnetic reference layer 16 is a downward direction as an example in FIGS. 10(a) and 10(b), the same effects as above can be achieved even if the magnetization direction of the magnetic reference layer 16 is reversed to an upward direction, and the direction of the current flowed to the magnetoresistive element 1 is also reversed.

Although FIGS. 10(a) and 10(b) show the results of simulations in which the current required for spin injection writing is smaller than the current required for resonant magnetic field writing, the current required for resonant magnetic field writing can be reduced by changing magnetic parameters of the magnetic rotation layer 20. The rotational frequency of the magnetic rotation layer 20 with respect to the density of the applied current is proportional to the gyromagnetic constant y of the magnetic rotation layer 20, and is inversely proportional to the damping constant α, the polarizability P, the saturation magnetization Mₛ, and the film thickness t, as shown in the equation (1). Therefore, the magnetic parameters of the magnetic rotation layer are optimized so that the rotational frequency of the magnetic rotation layer 20 becomes almost the same as the resonant frequency of the magnetic recording layer 12 at a lower current density than the current density required for spin-transfer torque writing. In this manner, the current required for resonant magnetic field writing can be made smaller than the current required for spin-transfer torque writing.

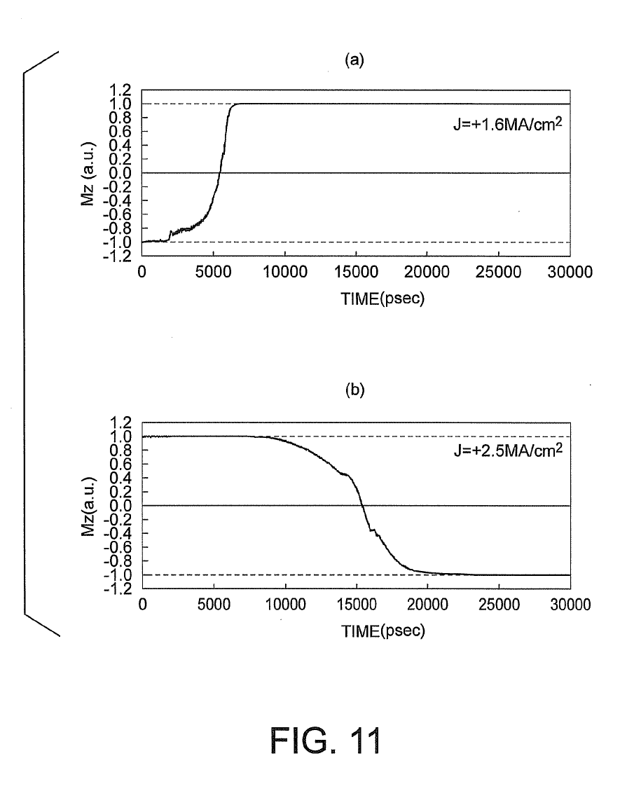

FIGS. 11(a) and 11(b) each show the result of writing using a unidirectional current calculated through an LLG simulation in a case where the magnetic parameters of the magnetic rotation layer 20 are optimized, and the current density for resonant magnetic field writing is low. As can be seen from FIGS. 11(a) and 11(b), a magnetization reversal from a parallel state to an antiparallel state is caused by resonant magnetic field writing at a current density of 1.6 MA/cm², and a magnetization reversal from an antiparallel state to a parallel state is caused by spin-transfer torque writing at a current density of 2.5 MA/cm². Even when the current density required for resonant magnetic field writing is lower than the current density required for spin-transfer torque writing, a magnetization direction reversal can be caused in accordance with the information “0” or “1” by changing the current density of the unidirectional current in the magnetoresistive element 1 of this embodiment. In the case where the current density for resonant magnetic field writing is lower than the current density for spin-transfer torque writing, the write current in the magnetoresistive element 1 can be made smaller than in the opposite case.

As described above, this embodiment can provide a magnetoresistive element that is capable of performing stable writing without a writing error by using a unidirectional current.

### Second Embodiment

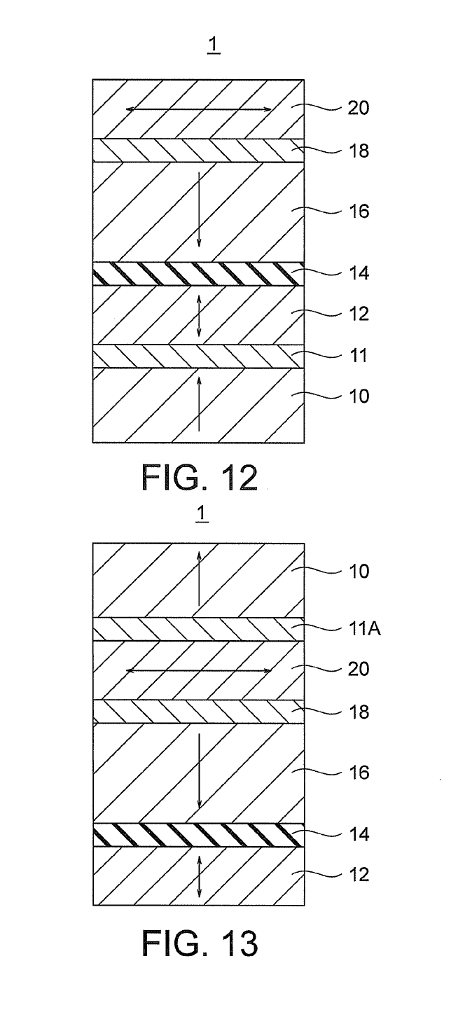

Generally, in a magnetoresistive element using a magnetic film (a perpendicular magnetization film) having perpendicular magnetization, a magnetic field strayed from the magnetic reference layer acts on the magnetic recording layer, and the stability of the information “0” and “1” becomes asymmetrical. In view of this, a magnetoresistive element according to a second embodiment includes a field adjustment layer having magnetization in the opposite direction from the magnetization of the magnetic reference layer, so as to reduce the influence of the magnetic field strayed from the magnetic reference layer. FIG. 12 shows the magnetoresistive element of the second embodiment. The magnetoresistive element 1 of the second embodiment is the same as the magnetoresistive element of the first embodiment shown in FIG. 5, except that a field adjustment layer 10 is provided on the opposite side of the magnetic recording layer 12 from the side on which the tunnel barrier layer 14 is provided, with a nonmagnetic metal layer 11 being interposed between the field adjustment layer 10 and the magnetic recording layer 12. The material of the nonmagnetic metal layer 11 may be a metal made of only one element selected from the group consisting of Cu, Au, Ag, and Ru, or an alloy containing at least one of those elements.

As in a magnetoresistive element 1 according to a modification of the second embodiment shown in FIG. 13, a field adjustment layer 10 may be provided on the opposite side of the magnetic rotation layer 20 from the side on which the spacer layer 18 is provided in the first embodiment shown in FIG. 5, with a nonmagnetic layer 11A being interposed between the field adjustment layer 10 and the magnetic rotation layer 20. The nonmagnetic layer 11A in this modification may be a metal layer that does not pass spin-polarized electrons or a tunnel barrier layer. However, the nonmagnetic layer 11A is preferably a nonmagnetic layer that passes spin-polarized electrons, and is preferably made of a metal formed only with one element selected from the group consisting of Cu, Au, Ag, and Ru, an alloy containing at least one of those elements, or an oxide or nitride containing one element selected from the group consisting of Mg, Al, Ti, and Hf. As one of those materials is used as the nonmagnetic layer 11A, the amount of spin injection into the magnetic rotation layer 20 becomes larger. Accordingly, efficient rotation can be caused in the magnetic rotation layer 20.

In the second embodiment and its modification, stable writing can be performed without a writing error by using a unidirectional current, as in the first embodiment. Also, the influence of the magnetic field strayed from the magnetic reference layer 16 can be made smaller than in the first embodiment. Accordingly, the information recorded in the magnetic recording layer 12 can be made more stable.

### Third Embodiment

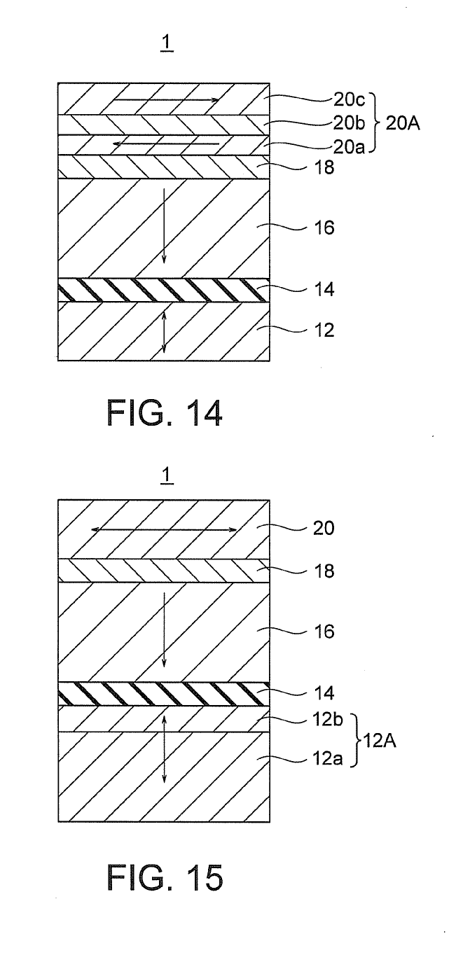

FIG. 14 shows a magnetoresistive element according to a third embodiment. The magnetoresistive element 1 of the third embodiment is the same as the magnetoresistive element of the first embodiment shown in FIG. 5, except that a synthetic antiferromagnetic coupling film 20A is used in place of the magnetic rotation layer 20. In the synthetic antiferromagnetic coupling film 20A, a ferromagnetic layer 20a, a nonmagnetic layer 20b, and a ferromagnetic layer 20c are stacked in this order on the spacer layer 18, and form a stack structure. The ferromagnetic layer 20a and the ferromagnetic layer 20c are antiferromagnetically coupled to each other via the nonmagnetic layer 20b.

In each of the magnetoresistive elements according to the first and second embodiments, a magnetic film (an in-plane magnetization film) having in-plane magnetization is used as the magnetic rotation layer 20, and therefore, a complicated magnetic domain structure such as a vortex domain structure might appear. If there is a magnetic domain structure, rotations caused at the time of spin injection from the magnetic reference layer 16 interfere with each other, resulting in a decrease in rotation efficiency. Therefore, it is preferable that no magnetic domain structures appear in the magnetic rotation layer 20. In general, as the device size is made smaller, an in-plane magnetization film turns into a single domain, and no magnetic domain structures appear. Further, to avoid magnetic domain structures in the magnetic rotation layer 20, which is an in-plane magnetization film, a synthetic antiferromagnetic coupling film should be used as the magnetic rotation layer 20A, as in the third embodiment.

Accordingly, the magnetoresistive element 1 of the third embodiment can prevent a decrease in the rotation efficiency of the magnetic rotation layer 20A. Also, the magnetoresistive element 1 of the third embodiment can perform stable writing without a writing error by using a unidirectional current, as in the first embodiment.

In the third embodiment, the ferromagnetic layers 20a and 20c of the synthetic antiferromagnetic coupling film 20A can be made to have different film thicknesses, so that the direction of rotation of the microwave magnetic field applied from the magnetic rotation layer 20A to the magnetic recording layer 12 can be the opposite of the direction of rotation of a magnetic rotation layer formed with a single film.

### Fourth Embodiment

FIG. 15 shows a magnetoresistive element according to a fourth embodiment. The magnetoresistive element 1 of the fourth embodiment is the same as the magnetoresistive element of the first embodiment shown in FIG. 5, except that a stack-type magnetic recording layer 12A formed by stacking an in-plane magnetization film 12b on a perpendicular magnetization film 12a is used in place of the magnetic recording layer 12.

In each of the magnetoresistive elements of the first through third embodiments, the resonant frequency of the magnetic recording layer 12 is a critical parameter in resonant magnetic field writing. The resonant frequency of the magnetic recording layer 12 depends on the magnetic anisotropy energy, as expressed in the Kittel's equation, or the equation (5). Accordingly, the resonant frequency can be arbitrarily changed by using the stack-type magnetic recording layer 12A as the magnetic recording layer as in the fourth embodiment. Here, the in-plane magnetization film 12b does not have a perpendicular magnetic anisotropy, but the magnetization direction is switched to a perpendicular direction as shown in FIG. 15 when the in-plane magnetization film 12b is exchange-coupled to the perpendicular magnetization film 12a. Normally, the entire magnetic anisotropy energy decreases when an in-plane magnetization film is stacked on a perpendicular magnetization film. Accordingly, the resonant frequency of the magnetic recording layer 12A of the fourth embodiment can be adjusted to a desired frequency. The perpendicular magnetization film 12a is preferably formed with a magnetic material having an L1₀ crystal structure that contains at least one element selected from the group consisting of Fe, Co, and Ni, and at least one element selected from the group consisting of Pt and Pd, or is formed with a magnetic material having a hexagonal crystal structure that contains at least one element selected from the group consisting of Fe, Co, and Ni, and at least one element selected from the group consisting of Cr, Ta, Pt, and Pd. In those cases, the in-plane magnetization film 12b may be made of an alloy containing at least one element selected from the group consisting of Fe, Co, Ni, and Mn.

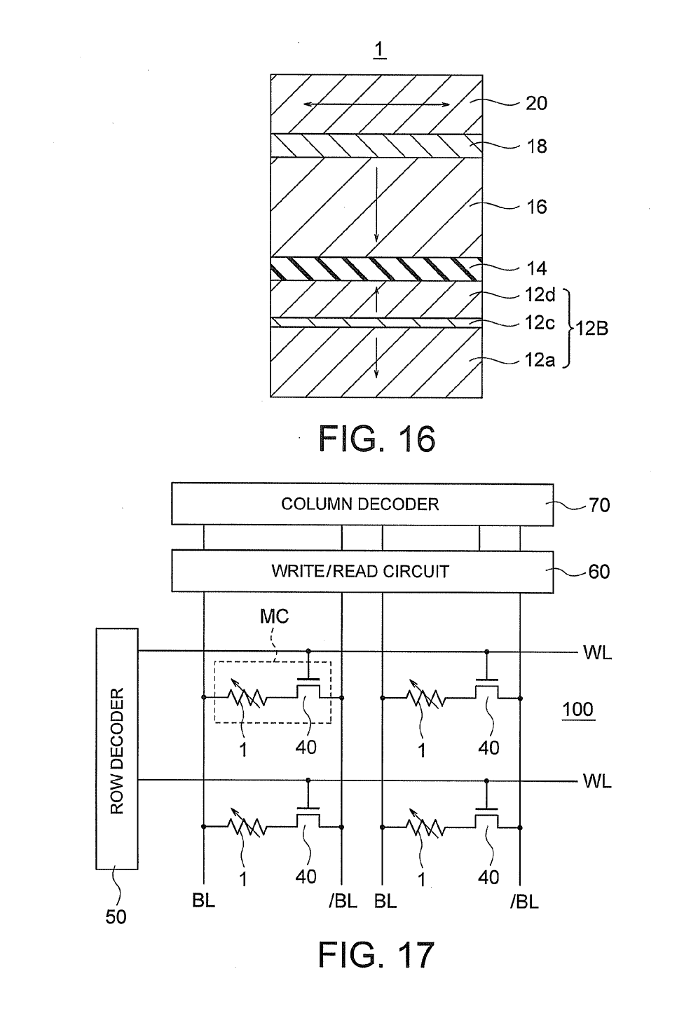

Also, as in a magnetoresistive element 1 of a modification shown in FIG. 16, a perpendicular SAF coupling film 12B, in which a spacer layer 12c containing one element selected from the group consisting of Cu, Au, Ag, and Ru is provided between a perpendicular magnetization film 12a and a perpendicular magnetization film 12d, may be used to form a magnetic recording layer 12B having a larger variation in resonant frequency than that in the first through third embodiments.

The fourth embodiment and its modification can realize stable writing without a writing error by using a unidirectional current, like the first embodiment.

Any appropriate combination of the second through fourth embodiments can realize stable writing without a writing error by using a unidirectional current, like the first embodiment.

### Fifth Embodiment

FIG. 17 shows a magnetic random access memory (MRAM) according to a fifth embodiment.

The MRAM of this embodiment includes a memory cell array 100 having memory cells MC arranged in a matrix fashion. Each of the memory cells MC includes a magnetoresistive element 1 according to one of the first through fourth embodiments and the modifications thereof, or a combination of some of those embodiments and modifications.

In the memory cell array 100, pairs of bit lines BL and /BL are arranged so that each of the pairs extends in the column direction. Also, in the memory cell array 100, word lines WL are arranged so that each of the word lines WL extends in the row direction.

The memory cells MC are arranged at the intersection portions between the bit lines BL and the word lines WL. Each of the memory cells MC includes a magnetoresistive element 1 and a select transistor 40. One end of the magnetoresistive element 1 is connected to a bit line BL. The other end of the magnetoresistive element 1 is connected to the drain terminal of the select transistor 40. The gate terminal of the select transistor 40 is connected to a word line WL. The source terminal of the select transistor 40 is connected to a bit line /BL.

A row decoder 50 is connected to the word lines WL. A write/read circuit 60 is connected to the pairs of bit lines BL and /BL. A column decoder 70 is connected to the write/read circuit 60. Each of the memory cells MC is selected by the row decoder 50 and the column decoder 70.

Data is written into a memory cell MC in the following manner. First, to select the memory cell MC into which data is to be written, the word line WL connected to the memory cell MC is activated. As a result, the select transistor 40 is turned on.

At this point, a write current flowing only in one direction should be supplied to the magnetoresistive element 1. Specifically, when a write current Iw is supplied to the magnetoresistive element 1 from left to right in the drawing, the write circuit in the write/read circuit 60 applies a positive potential to the bit lint BL, and applies a ground potential to the bit line /BL. In this manner, data “0” or data “1” can be written into the memory cell MC.

Data is read from a memory cell MC in the following manner. First, a memory cell MC is selected. The read circuit in the write/read circuit 60 supplies a read current Ir flowing from right to left in the drawing to the magnetoresistive element 1, for example.

Based on the read current Ir, the read circuit detects the resistance value of the magnetoresistive element 1. In this manner, the information stored in the magnetoresistive element 1 can be read out. With the MRAM of the fifth embodiment, there is no need to prepare a peripheral circuit for flowing a write current bi-directionally. Accordingly, a large-capacity MRAM with high cell occupancy is readily realized.

### Sixth Embodiment

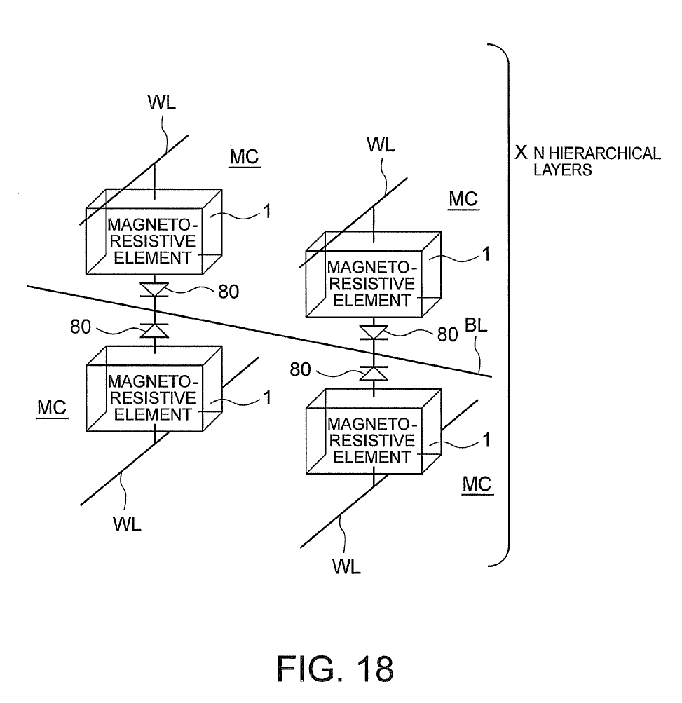

FIG. 18 shows a MRAM according to a sixth embodiment. The MRAM of the sixth embodiment has a cross-point architecture. Specifically, the MRAM of the sixth embodiment includes memory cells MC each including a magnetoresistive element 1 according to one of the first through fourth embodiments and a diode 80, between a bit line BL and word lines WL. The diode 80 may be a PN diode or a schottky diode. Instead of the diode 80, a rectifier having a rectifying function to flow a current only in one direction may be used. In FIG. 18, the diodes 80 are provided on the bit line side, but may be provided on the sides of the word lines WL.

In the sixth embodiment, a current can be applied only in one direction. For writing, the first and second write currents described in the first embodiment are preferably used. The read current preferably has a current value such that the magnetic rotation layer 20 generates a microwave magnetic field having a different rotational frequency from the resonant frequency of the magnetic recording layer 12, and the magnetization direction of the magnetic recording layer 12 is not reversed by spin injection.

In this case, a memory cell MC on which writing or reading is to be performed can be selected by a combination of a row decoder and a column decoder. In the MRAM of the sixth embodiment, there is no need to mount a select transistor on each memory cell. Accordingly, a large-capacity MRAM with high cell occupancy can be realized.

As illustrated in FIG. 18, the MRAM of the sixth embodiment can be formed as a stack-type MRAM, if cross-point architectures are provided in the lower layer and the upper layer, and a line corresponding to the same location in the cross-point architectures in the lower layer and the upper layer, or a bit line BL, is shared. Also, if the circuit structure illustrated in FIG. 18 is turned into a unit hierarchy, an extremely large memory can be formed, in principle, by stacking N hierarchical layers and increasing the capacity per unit area by N times.

While certain embodiments have been described, these embodiments have been presented by way of example only, and are not intended to limit the scope of the inventions. Indeed, the novel methods and systems described herein can be embodied in a variety of other forms; furthermore, various omissions, substitutions and changes in the form of the methods and systems described herein can be made without departing from the spirit of the inventions. The accompanying claims and their equivalents are intended to cover such forms or modifications as would fall within the scope and spirit of the inventions.

1. A magnetoresistive element comprising:
a first ferromagnetic layer having changeable magnetization substantially perpendicular to a film plane;
a second ferromagnetic layer having fixed magnetization substantially perpendicular to the film plane;
a first nonmagnetic layer provided between the first ferromagnetic layer and the second ferromagnetic layer;
a third ferromagnetic layer provided on the opposite side of the second ferromagnetic layer from the first nonmagnetic layer, the third ferromagnetic layer having magnetization substantially parallel to the film plane, the third ferromagnetic layer generating a rotating magnetic field when spin-polarized electrons are injected thereinto; and
a second nonmagnetic layer provided between the second ferromagnetic layer and the third ferromagnetic layer, wherein
the magnetization of the first ferromagnetic layer is reversed by the rotating magnetic field generated from the third ferromagnetic layer when a first current is flowed in one of a direction from the third ferromagnetic layer toward the first ferromagnetic layer via the second ferromagnetic layer and a direction from the first ferromagnetic layer toward the third ferromagnetic layer via the second ferromagnetic layer, and,
when a second current having a different current density from the first current is flowed in the one direction, the magnetization of the first ferromagnetic layer is reversed by electrons spin-polarized by the second ferromagnetic layer to a different direction from the magnetization caused when the first current is flowed.

2. The magnetoresistive element according to claim 1, wherein the third ferromagnetic layer has a stack structure including first and second ferromagnetic films each having a magnetization direction substantially parallel to the film plane, and a third nonmagnetic layer located between the first and second ferromagnetic films, the first and second ferromagnetic films being antiferromagnetically coupled to each other, the third nonmagnetic layer being interposed between the first and second ferromagnetic films.

3. The magnetoresistive element according to claim 1, wherein a fourth ferromagnetic layer having magnetization in the opposite direction from the magnetization direction of the second ferromagnetic layer is provided on the opposite side of the first ferromagnetic layer from the first nonmagnetic layer via a third nonmagnetic layer, or on the opposite side of the third ferromagnetic layer from the second nonmagnetic layer via the third nonmagnetic layer.

4. The magnetoresistive element according to claim 1, wherein the first nonmagnetic layer is an oxide containing one element selected from the group consisting of Mg, Al, Ti, and Hf.

5. The magnetoresistive element according to claim 1, wherein the second nonmagnetic layer is a metal containing one element selected from the group consisting of Cu, Au, Ru, and Ag.

6. The magnetoresistive element according to claim 1, wherein the first ferromagnetic layer is one of:
a magnetic material having a L1₀ crystal structure containing at least one element selected from the group consisting of Fe, Co, and Ni, and at least one element selected from the group consisting of Pt and Pd; and
a magnetic material having a hexagonal crystal structure containing at least one element selected from the group consisting of Fe, Co, and Ni, and at least one element selected from the group consisting of Cr, Ta, Pt, and Pd.

7. The magnetoresistive element according to claim 1, wherein the first ferromagnetic layer has a stack structure including:
a magnetic material having an L1₀ crystal structure containing at least one element selected from the group consisting of Fe, Co, and Ni, and at least one element selected from the group consisting of Pt and Pd; and
an alloy containing at least one element selected from the group consisting of Fe, Co, Ni, and Mn.

8. The magnetoresistive element according to claim 1, wherein the first ferromagnetic layer has a stack structure including:
a magnetic material having a hexagonal crystal structure containing at least one element selected from the group consisting of Fe, Co, and Ni, and at least one element selected from the group consisting of Cr, Ta, Pt, and Pd; and
an alloy containing at least one element selected from the group consisting of Fe, Co, Ni, and Mn.

9. The magnetoresistive element according to claim 1, wherein a frequency of the rotating magnetic field is within a predetermined range including a resonant frequency of the first ferromagnetic layer.

10. The magnetoresistive element according to claim 1, wherein the rotating magnetic field is a microwave magnetic field.

11. A magnetic random access memory comprising:
the magnetoresistive element according to claim 1;
a first line electrically connected to the first ferromagnetic layer of the magnetoresistive element via a first electrode; and
a second line electrically connected to the third ferromagnetic layer of the magnetoresistive element via a second electrode.

12. The magnetic random access memory according to claim 11, further comprising
a select transistor provided between the first electrode and the first line or between the second electrode and the second line.

13. The magnetic random access memory according to claim 11, further comprising
a rectifier provided between the first electrode and the first line or between the second electrode and the second line.

14. The magnetic random access memory according to claim 11, wherein the third ferromagnetic layer has a stack structure including first and second ferromagnetic films each having a magnetization direction substantially parallel to the film plane, and a third nonmagnetic layer located between the first and second ferromagnetic films, the first and second ferromagnetic films being antiferromagnetically coupled to each other, the third nonmagnetic layer being interposed between the first and second ferromagnetic films.

15. The magnetic random access memory according to claim 11, wherein a fourth ferromagnetic layer having magnetization in the opposite direction from the magnetization direction of the second ferromagnetic layer is provided on the opposite side of the first ferromagnetic layer from the first nonmagnetic layer via a third nonmagnetic layer, or on the opposite side of the third ferromagnetic layer from the second nonmagnetic layer via the third nonmagnetic layer.

16. The magnetic random access memory according to claim 11, wherein the first nonmagnetic layer is an oxide containing one element selected from the group consisting of Mg, Al, Ti, and Hf.

17. The magnetic random access memory according to claim 11, wherein the second nonmagnetic layer is a metal containing one element selected from the group consisting of Cu, Au, Ru, and Ag.

18. The magnetic random access memory according to claim 11, wherein the first ferromagnetic layer is one of:
a magnetic material having a L1₀ crystal structure containing at least one element selected from the group consisting of Fe, Co, and Ni, and at least one element selected from the group consisting of Pt and Pd; and
a magnetic material having a hexagonal crystal structure containing at least one element selected from the group consisting of Fe, Co, and Ni, and at least one element selected from the group consisting of Cr, Ta, Pt, and Pd.

19. The magnetic random access memory according to claim 11, wherein the first ferromagnetic layer has a stack structure including:
a magnetic material having an L1₀ crystal structure containing at least one element selected from the group consisting of Fe, Co, and Ni, and at least one element selected from the group consisting of Pt and Pd; and
an alloy containing at least one element selected from the group consisting of Fe, Co, Ni, and Mn.

20. The magnetic random access memory according to claim 11, wherein the first ferromagnetic layer has a stack structure including:
a magnetic material having a hexagonal crystal structure containing at least one element selected from the group consisting of Fe, Co, and Ni, and at least one element selected from the group consisting of Cr, Ta, Pt, and Pd; and
an alloy containing at least one element selected from the group consisting of Fe, Co, Ni, and Mn.
